(19) United States
(12) Patent Application Publication
(10) Pub. No.: US 2018/0308995 A1
(43) Pub. Date: Oct. 25, 2018

(54) PHOTOELECTRIC CONVERSION ELEMENT

(71) Applicant: Solar Frontier K.K., Tokyo (JP)

(72) Inventors: Shunsuke ADACHI, Tokyo (JP); Rui KAMADA, Tokyo (JP); Homare HIROI, Tokyo (JP)

(73) Assignee: Solar Frontier K.K., Tokyo (JP)

(21) Appl. No.: 15/769,257

(22) PCT Filed: Sep. 28, 2016
(86) PCT No.: PCT/JP2016/078718

§ 371 Date: Apr. 18, 2018

(30) Foreign Application Priority Data
Oct. 19, 2015 (JP) 2015-205591

(51) Int. Cl. H01L 31/0224; H01L 31/073; H01L 31/0749

(52) U.S. Cl. CPC H01L 31/022408; H01L 31/0749; H01L 31/022483; H01L 31/073

(57) ABSTRACT

A photoelectric conversion element comprises: a first electrode layer 12; a compound-based photoelectric conversion layer 13 disposed on the first electrode layer 12; a buffer layer 15 disposed on the compound-based photoelectric conversion layer 13 comprising a mixed crystal of ZnO and ZnS, wherein a ratio of the number of S atoms to the number of Zn atoms is in a range of 0.290 to 0.493; and a second electrode layer 16 disposed on the buffer layer 15.

### CROSS REFERENCE TO RELATED APPLICATIONS

This application is a U.S. National phase patent application of International Patent Application No. PCT/JP2016/078718, filed Sep. 28, 2016 which claims priority of Japanese Patent Application No. JP 2015-205591, filed Oct. 19, 2015, the contents of which are hereby incorporated by reference in the present disclosure in its entirety.

### FIELD OF THE INVENTION

The present invention relates to a photoelectric conversion element.

### BACKGROUND OF THE INVENTION

Recently, a photoelectric conversion element including a compound-based semiconductor as a photoelectric conversion layer is known.

For example, as such photoelectric conversion elements, a CdTe-based photoelectric conversion element in which the compound-based semiconductor includes Cd and Te, or a chalcogenide-based photoelectric conversion element in which the compound-based semiconductor includes a chalcogenide element (e.g., S or Se) is known.

Examples of the chalcogenide-based photoelectric conversion elements include a CIS-based photoelectric conversion element including a group compound semiconductor and a CZTS-based photoelectric conversion element including a I-(II-IV)-VI group compound semiconductor.

The above-mentioned compound-based semiconductor is used as a compound-based photoelectric conversion layer having p-type conductivity, and the photoelectric conversion element is formed by sequentially laminating a first electrode layer, a compound-based photoelectric conversion layer, a buffer layer and a second electrode layer on a substrate.

A buffer layer is transparent and has n-type conductivity or i-type conductivity (intrinsic). When a buffer layer has n-type conductivity, a pn junction is formed by laminating a compound-based photoelectric conversion layer and a buffer layer. In addition, when a buffer layer has i-type conductivity, pin junction is formed by laminating a compound-based photoelectric conversion layer, the buffer layer and a second electrode layer having n-type conductivity.

As a buffer layer, a Cd-based buffer layer including Cd, Zn-based buffer layer including Zn or In-based buffer layer including In is known.

Among these buffer layers, Zn-based buffer layer is attracting much interest from the viewpoint of being free from Cd which is a hazardous substance and In which is a rare metal. Moreover, Zn-based buffer layer is attracting much interest from the viewpoint of achieving high photoelectric conversion property.

Specific examples of the materials for forming a Zn-based buffer layer include ZnO, ZnS, Zn(OH)₂, or Zn(O, S), Zn(O, S, OH) which are mixed crystals thereof, and ZnMgO, ZnSnO.

A photoelectric conversion element generates electricity in such a way that sunlight transmits through a transparent second electrode layer and buffer layer and is absorbed in a compound-based photoelectric conversion layer.

### PATENT LITERATURE

Patent literature 1: Japanese Unexamined Patent Publication (Kokai) No. 2009-135337

Patent literature 2: International Publication WO 2009/110093

### BRIEF SUMMARY OF THE INVENTION

The above-mentioned buffer layer affects a photoelectric conversion property of a photoelectric conversion element.

Specifically, a film-quality of a buffer layer such as defects affects a photoelectric conversion property of a photoelectric conversion element. Examples of the photoelectric conversion properties of a photoelectric conversion element include a photoelectric conversion efficiency or leakage current.

However, relationships between a film-quality of a buffer layer such as defects and a photoelectric conversion property of a photoelectric conversion element are mostly unclarified.

It is expected that a photoelectric conversion property of a photoelectric conversion element will be improved by controlling a film-quality of a buffer layer.

An object herein is to provide a photoelectric conversion element whereby the above-mentioned problems may be solved.

A photoelectric conversion element disclosed herein includes: a first electrode layer; a compound-based photoelectric conversion layer disposed on the first electrode layer; a buffer layer disposed on the compound-based photoelectric conversion layer comprising a mixed crystal of ZnO and ZnS, wherein a ratio of the number of S atoms to the number of Zn atoms is in a range of 0.290 to 0.493; and a second electrode layer disposed on the buffer layer.

According to the photoelectric conversion element mentioned above, the buffer layer includes a mixed crystal of ZnO and ZnS and the ratio of the number of S atoms to the number of Zn atoms is in a range of 0.290 to 0.493, whereby a photoelectric conversion property is enhanced.

### BRIEF DESCRIPTION OF THE DRAWINGS

FIG. 1 is a view depicting one embodiment of the photoelectric conversion element disclosed herein.

FIG. 2 is a view explaining manufacturing process No. 1 for the photoelectric conversion element disclosed herein.

FIG. 3 is a view explaining manufacturing process No. 2 for the photoelectric conversion element disclosed herein.

FIG. 4 is a view explaining manufacturing process No. 3 for the photoelectric conversion element disclosed herein.

FIG. 5 is a view explaining manufacturing process No. 4 for the photoelectric conversion element disclosed herein.

FIG. 6 is a drawing explaining each specific resistance and change rate of specific resistance of the buffer layers of Experimental Examples and Comparative Experimental Examples.

FIG. 7 is a drawing explaining photoelectric conversion properties of each photoelectric conversion element of Experimental Examples and Comparative Experimental Examples.

### DETAILED DESCRIPTION OF THE INVENTION

Hereinafter, preferable embodiments of the photoelectric conversion elements disclosed herein will be described with reference to drawings. It is noted that the scope of the present invention is not limited to these embodiments and embraces the inventions described in the claims and equivalents thereto.

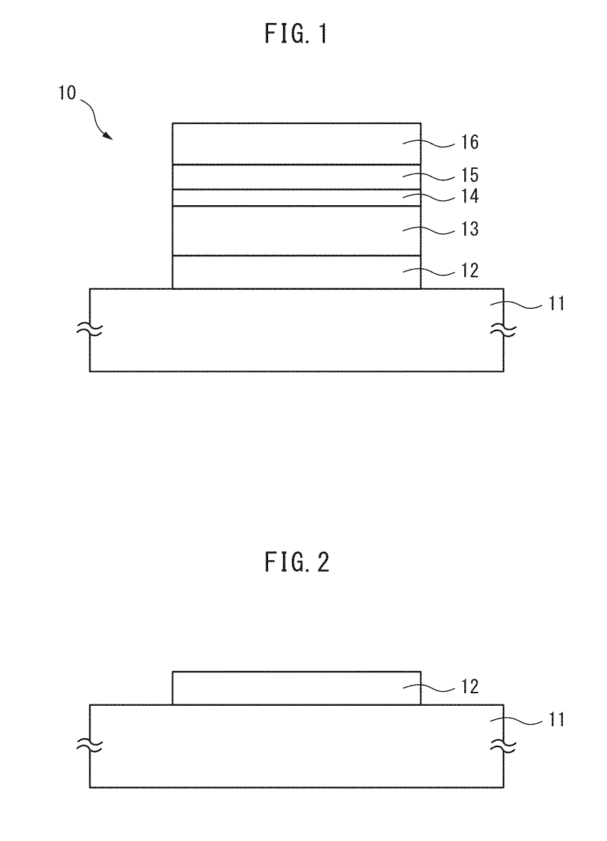

FIG. 1 is a view depicting one embodiment of the photoelectric conversion element disclosed herein.

The photoelectric conversion element 10 according to the embodiment includes a substrate 11, a first electrode layer 12 disposed on the substrate 11, a compound-based photoelectric conversion layer 13 disposed on the first electrode layer 12 which compound-based photoelectric conversion layer has p-type conductivity, a seed layer 14 disposed on the compound-based photoelectric conversion layer 13 which seed layer has n-type conductivity, a buffer layer 15 disposed on the seed layer 14 which buffer layer has n-type conductivity and high-resistance, and a second electrode layer 16 disposed on the buffer layer 15 which second electrode layer has n-type conductivity.

As a compound-based photoelectric conversion layer 13, a chalcogenide-based compound semiconductor or CdTe-based compound semiconductor can be used. Examples of the chalcogenide-based compound semiconductors include a group compound semiconductor or I-(II-IV)-VI group compound semiconductor.

The seed layer 14 promotes crystal growth of the buffer layer 15.

The buffer layer 15 includes a mixed crystal of ZnO and ZnS. ZnO is a compound of Zn (zinc) and O (oxygen). ZnS is a compound of Zn (zinc) and S (sulfur).

From the viewpoint of enhancing a photoelectric conversion efficiency or photoelectric conversion property such as a parallel resistance, a ratio of the number of S atoms to the number of Zn atoms in the buffer layer 15 is in a range of 0.290 to 0.493.

Next, one preferable embodiment of a process for manufacturing the above-mentioned photoelectric conversion element 10 will be described below with reference to FIGS. 2 to 5.

First, as depicted as FIG. 2, a first electrode layer 12 is formed on a substrate 11. As the substrate 11, for example, glass substrates such as soda lime glass, high strain point glass or low alkaline glass, metal substrates such as stainless plates, or resin substrate such as polyimide resins can be used. The substrate 11 may include an alkaline metal element such as sodium and potassium.

As the first electrode layer 12, for example, a metal conductive layer formed with a metal such as Mo, Cr, and/or Ti as a material can be used. It is preferable that a material for forming a metal conductive layer has lower reactivity to VI group elements such as S from the viewpoint of preventing corrosion of the first electrode layer 12 when a photoelectric conversion layer is formed using a selenization method or sulfurization method. It is preferable that the photoelectric conversion element 10 have a transparent substrate 11 and transparent first electrode layer 12 when a so-called layered product for tandem-type photoelectric conversion element in which a photoelectric conversion element 10 is disposed on the other photoelectric conversion element. The phrase “The substrate 11 and first electrode layer 12 are transparent” means herein that they are transparent to light of a wavelength which the other photoelectric conversion element disposed underneath absorbs. Note that the photoelectric conversion element 10 may include no substrate. In addition, as a material for the transparent first electrode layer 12, zinc oxide doped with a III group element (Ga, Al, and/or B), ITO (Indium Tin Oxide) and the like are preferable. A thickness of the first electrode layer 12 can be, for example, 0.1 to 1 μm. The first electrode layer 12 is formed using, for example, a sputtering (DC, RF) method, chemical vapor deposition method (CVD method), atomic layer deposition method (ALD method), vapor deposition method and ion plating method.

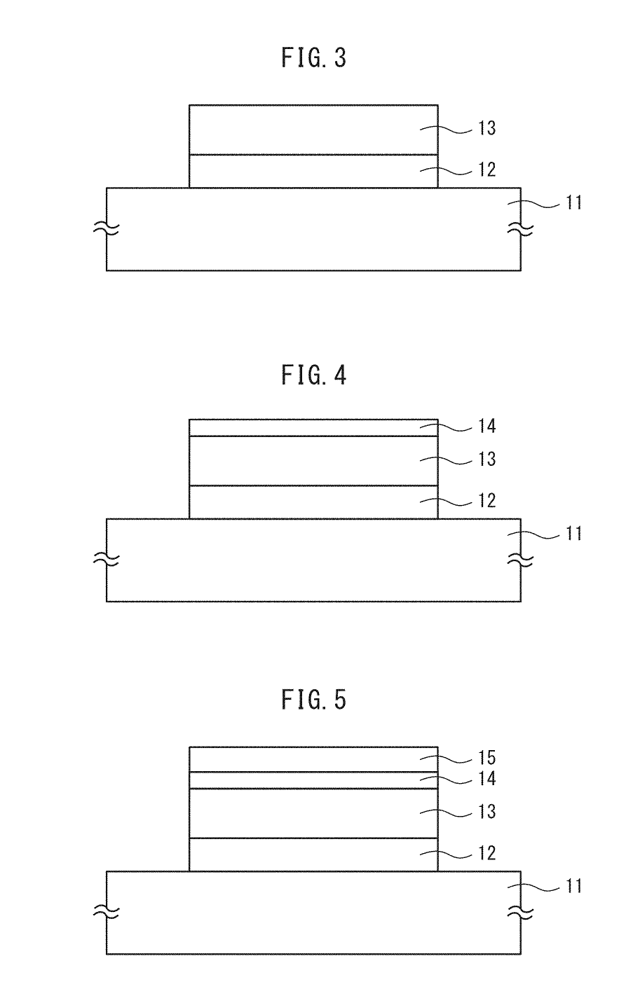

Subsequently, as depicted in FIG. 3, the compound-based photoelectric conversion layer 13 having p-type conductivity is formed on the first electrode layer 12.

As the compound-based photoelectric conversion layer 13, for example, a CIS-based compound semiconductor formed by a group compound (may be also referred to as I-III-VI₂ group compound) or a CZTS-based compound semiconductor formed by a I-(II-IV)-VI group compound semiconductor (may be also referred to as I₂-(II-IV)-VI₄ group compound semiconductor) can be used.

A thickness of the compound-based photoabsorbing layer 13 can be, for example, 1 to 3 μm.

In case of the CIS-based compound semiconductor, as a I group element, for example, copper (Cu), silver (Ag) or gold (Au) can be used. As a III group element, for example, gallium (Ga), indium (In) or Al (aluminum) can be used. As a VI group element, for example, selenium (Se), sulfur (S), oxygen (O) or tellurium (Te) can be used. Specific examples of the CIS-based compound semiconductors include Cu(In, Ga)Se₂, Cu(In, Ga)(Se, S)₂, CuInS₂.

Examples of methods for forming the CIS-based compound semiconductor include (1) a method in which a precursor film of a I group element and III group element is formed and a compound of the precursor film and a VI group element is then formed (a selenization method or sulfurization method) and (2) a method in which a film including a I group element, III group element and VI group element is deposited using a vapor deposition method (a vapor deposition method).

(Selenization Method or Sulfurization Method)

Examples of methods for forming the precursor film include a sputtering method, vapor deposition method or ink coating method. A sputtering method is a method in which deposition is carried out using atoms discharged from a target by collision of ions or the like with the target using a sputtering source as the target. A vapor deposition method is a method in which deposition is carried out using atoms or the like vaporized by heating a vapor deposition source. An ink coating method is a method in which a precursor film is formed by dispersing a powder of a material for the precursor film in a solvent such as organic solvents, coating the resultant mixture on a first electrode layer, and evaporating the solvent.

As a sputtering source or vapor deposition source including Cu as a I group element, Cu alone, Cu—Ga including Cu and Ga, Cu—Ga—In including Cu, Ga and In, and the like can be used. As a sputtering source or vapor deposition source including Ga as a III group element, Cu—Ga including Cu and Ga, Cu—Ga—In including Cu, Ga and In, and the like can be used. As a sputtering source or vapor deposition source including In as a III group element, In alone, Cu—In including Cu and In, Cu—Ga—In including Cu, Ga and In, and the like can be used.

A precursor film including Cu, In and Ga may be configured as a layer alone or laminated layers, formed using the above-mentioned sputtering method or vapor deposition method.

Specific examples of the precursor films include Cu—Ga—In, Cu—Ga/Cu—In, Cu—In/Cu—Ga, Cu—Ga/Cu/In, Cu—Ga/In/Cu, Cu/Cu—Ga/In, Cu/In/Cu—Ga, In/Cu—Ga/Cu, In/Cu/Cu—Ga, Cu—Ga/Cu—In/Cu, Cu—Ga/Cu/Cu—In, Cu—In/Cu—Ga/Cu, Cu—In/Cu/Cu—Ga, Cu/Cu—Ga/Cu—In, Cu/Cu—In/Cu—Ga. In addition, the precursor film may include a multiply-stacked structure in which these films are further laminated.

The above-mentioned Cu—Ga—In herein means a single film. In addition, “/” means a layered product of left and right layers. For example, Cu—Ga/Cu—In means a layered product of a Cu—Ga film and a Cu—In film. Cu—Ga/Cu/In means a layered product of a Cu—Ga film, a Cu film and an In film.

The compound-based photoelectric conversion layer 13 is formed by reacting the above-mentioned precursor film with a VI group element. For example, a precursor film is heated under an atmosphere including sulfur and/or selenium of VI group elements to form a compound of the precursor film and sulfur and/or selenium (sulfurization and/or selenization) as the compound-based photoelectric conversion layer 13. Note that a precursor film may be formed in such a manner to include a VI group element.

(Vapor Deposition Method)

In a vapor deposition method, the compound-based photoelectric conversion layer 13 is formed by depositing on the first electrode layer 12 atoms or the like vaporized by heating a vapor deposition source including a I group element, a vapor deposition source including a III group element and a vapor deposition source including a VI group element or a vapor deposition source including these plural elements. As a vapor deposition source, those described in the above-mentioned precursor method can be used.

In case of the CZTS-based compound semiconductor, as a I group element, for example, copper (Cu), silver (Ag) or gold (Au) can be used. As a II group element, for example, zinc (Zn) can be used. As a IV group element, for example, tin (Sn) can be used. As a VI group element, for example, selenium (Se), sulfur (S), oxygen (O) or tellurium (Te) can be used. Specific examples of the CZTS-based compound semiconductors include Cu₂(Zn, Sn)Se₄, Cu₂(Zn, Sn)S₄, or Cu₂(Zn, Sn)(Se, S)₄ which is a mixed crystal thereof.

Examples of methods for forming the CZTS-based compound semiconductor include, as with CIS-based compound semiconductors, (1) a method in which a precursor film of a I group element and II group element is formed and a compound of the precursor film and a VI group element is then formed (a precursor method) and (2) a method in which a film including a I group element, II group element, IV group element and VI group element is deposited using a vapor deposition method (a vapor deposition method).

When a CZTS-based compound semiconductor is formed using a precursor method, a sputtering source or vapor deposition source including a II group element and IV group element along with the above-mentioned sputtering source or vapor deposition source including a I group element is used to form a precursor film and the CZTS-based compound semiconductor is then formed as a reactant of the precursor film and a VI group element.

When a CZTS-based compound semiconductor is formed using a vapor deposition method, the CZTS-based compound semiconductor is formed using a vapor deposition source including a II group element and a IV group element along with the above-mentioned vapor deposition source including a I group element and a VI group element.

Subsequently, as depicted in FIG. 4, the seed layer 14 having n-type conductivity is formed on the photoelectric conversion layer 13. It is preferable that the seed layer 14 is transparent to light of a wavelength absorbed by the photoelectric conversion layer 13. The seed layer 14 promotes crystal growth of the buffer layer 15 and the buffer layer 15 with less defects can be therefore formed by disposing the seed layer 14. In addition, the seed layer 14 promotes growth rate of the buffer layer 15.

As the seed layer 14, for example, a compound including Zn and a VI group element can be used. Examples of the compounds including Zn and a VI group element include ZnO, ZnS, Zn(OH)₂ or Zn(O, S) and Zn(O, S, OH) which are mixed crystals thereof.

As a method for forming the seed layer 14, a solution-growth method (chemical bath deposition method: CBD method), metal organic chemical vapor deposition method (MOCVD method), sputtering method, atomic layer deposition method (ALD method), vapor deposition method, ion plating method and the like can be used. Note that a CBD method is a method in which a substrate is immersed into a solution including a species for a precursor and a thin film is allowed to be deposited on the substrate by proceeding heterogeneous reaction of the solution and the surface of the substrate.

A thickness of the seed layer 14 can be, for example, 1 nm to 50 nm.

Subsequently, as depicted in FIG. 5, the buffer layer 15 having n-type conductivity and high-resistance is formed on the seed layer 14.

The buffer layer 15 is formed using a mixed crystal of ZnO and ZnOS as described above. The buffer layer 15 is formed in such a manner that a ratio of the number of S atoms to the number of Zn atoms is in a range of 0.290 to 0.493.

The buffer layer 15 forms a pn junction with the compound-based photoelectric conversion layer 13 together with the above-mentioned seed layer 14. In addition, the buffer layer 15 prevents forming a shunt path between the compound-based photoelectric conversion layer 13 and the second electrode layer 16 along with the seed layer 14 due to high-resistance and prescribed thickness, thereby increasing parallel resistance along with decreasing leakage current. Furthermore, it is preferable that a photoelectric conversion property (e.g., open-circuit voltage) is enhanced in such a way that the buffer layer 15 has a prescribed magnitude of spike between a lowest energy level of the conduction band of the compound-based photoelectric conversion layer 13 and a lowest energy level of the second electrode layer 16.

As a method for forming the buffer layer 15, for example, an atomic layer deposition method (ALD method), metal organic chemical vapor deposition method (MOCVD method), sputtering method, vapor deposition method, ion plating method, a solution-growth method (chemical bath deposition method: CBD method) and the like can be used.

The ratio of the number of S atoms to the number of Zn atoms in the buffer layer 15 is controlled by adjusting a supply amount of each element from a sulfur source (S source), zinc source (Zn source) and oxygen source (0 source) used when the buffer layer 15 is formed.

As a sulfur source, for example, hydrogen sulfide (H₂S) or sulfur vapor (e.g., formed by heating sulfur) can be used.

As a zinc source, for example, diethylzinc ((C₂H₅)₂Zn), triethylzinc ((C₂H₅)₃Zn), trimethylzinc ((CH)₃Zn) or other organic zinc compounds, or inorganic zinc compounds can be used.

As an oxygen source, for example, water (H₂O), oxides such as nitrogen monooxide (NO), carbon monooxide (CO), carbon dioxide (CO₂), or oxygen (O₂), ozone (O₃) or the like can be used.

When the buffer layer 15 is formed using, for example, ALD method, hydrogen sulfide (H₂S) can be used as a sulfur source, diethylzinc ((C₂H₅)₂Zn) can be used as a zinc source, and water (H₂O) can be used as an oxygen source.

It is preferable that the thickness of the buffer layer 15 be, for example, 10 to 200 nm, especially 20 to 150 nm.

The other buffer layer which has the same functions as the above-mentioned buffer layer 15 or a part of the functions and is formed using a material other than a mixed crystal of ZnO and ZnS may be arranged to superimpose the buffer layer 15.

Subsequently, the second electrode layer 16 is formed on the buffer layer 15 to obtain the photoelectric conversion element 10 as depicted in FIG. 1.

It is preferable that the second electrode layer 16 has n-type conductivity and is formed using a material of which forbidden band width is wide and resistance is low. In addition, it is preferable that the second electrode layer 16 is transparent to light of a wavelength absorbed by the compound-based photoelectric conversion layer 13.

The second electrode layer 16 is formed using, for example, a metal oxide into which a III group element (B, Al, Ga, In) has been added as a dopant. Specific examples include zinc oxide such as B:ZnO, Al:ZnO and Ga:ZnO, ITO (indium tin oxide) and SnO₂ (tin oxide). In addition, as the second electrode layer 16, ITiO, FTO, IZO or ZTO may be used.

As a method for forming the second electrode layer 16, for example, sputtering (DC, RF) method, chemical vapor deposition (CVD) method, atomic layer deposition method (ALD method), vapor deposition method, ion plating method and the like can be used.

A thickness of the second electrode layer 16 can be, for example, 1 to 3 μm.

An intrinsic zinc oxide film (i-ZnO) into which a dopant is not substantially added may be formed before the second electrode layer 16 is formed on the buffer layer 15, and the second electrode layer 16 is then formed on this intrinsic zinc oxide film. It is preferable that the thickness of the intrinsic zinc oxide film is in the range from 100 to 1000 nm, especially 200 to 500 nm. As a method for forming the intrinsic zinc oxide film, for example, an atomic layer deposition method (ALD method), metal organic chemical vapor deposition method (MOCVD method), sputtering method, vapor deposition method, ion plating method and the like can be used.

Note that CdTe-based compound semiconductor including Cd and Te may be used as the compound-based photoelectric conversion layer 13. In this case, the order for forming each layer may be inverse to the above.

According to the photoelectric conversion element of the above-mentioned embodiment, when the ratio of the number of S atoms to the number of Zn atoms in the buffer layer 15 is in a range of 0.290 to 0.493, excellent photoelectric conversion properties can be obtained. As specifically described below in Experimental Examples and Comparative Experimental Examples, the ratio of the number of S atoms to the number of Zn atoms in the buffer layer 15 is in a range of 0.290 to 0.493, whereby photoelectric conversion efficiency and parallel resistance are increased.

### EXAMPLES

Hereinafter, the buffer layer and photoelectric conversion element disclosed herein will be further described using Experimental Examples. However, the scope of the present invention is not limited to such Examples.

### Experimental Example 1

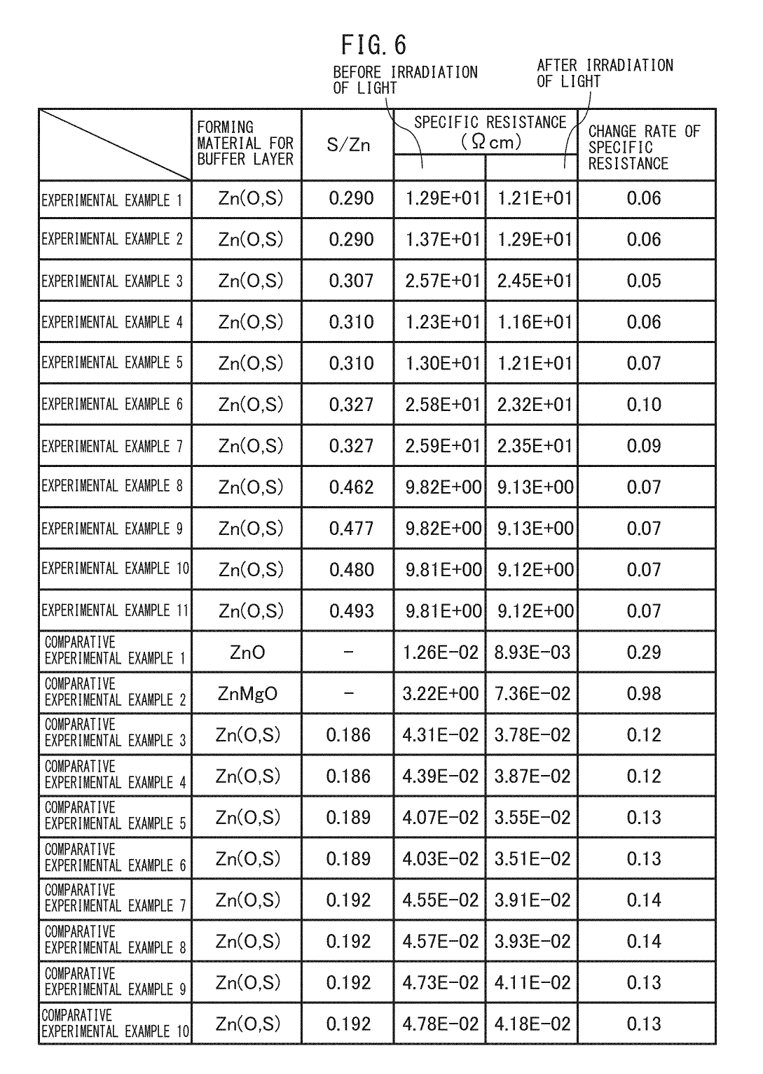

A buffer layer of a mixed crystal of ZnO and ZnS was formed on a glass substrate using an ALD method to obtain the buffer layer of Example 1. The ratio of the number of S atoms to the number of Zn atoms in the buffer layer (represented as S/Zn in FIG. 6) was 0.290. The number of S atoms and the number of Zn atoms in the buffer layer were measured using fluorescent X-ray analysis (XRF method). The numbers of S and Zn atoms of the Experimental Examples and Comparative Experimental Examples described below was measured in the same way as the above.

### Experimental Example 2

A buffer layer was formed in the same way as in Experimental Example 1 to obtain the buffer layer of Experimental Example 2. The ratio of the number of S atoms to the number of Zn atoms in the buffer layer was 0.290.

### Experimental Example 3

A buffer layer was formed in the same way as Experimental Example 1 to obtain the buffer layer of Experimental Example 3. The ratio of the number of S atoms to the number of Zn atoms in the buffer layer was 0.307.

### Experimental Example 4

A buffer layer was formed in the same way as Experimental Example 1 to obtain the buffer layer of Experimental Example 4. The ratio of the number of S atoms to the number of Zn atoms in the buffer layer was 0.310.

### Experimental Example 5

A buffer layer was formed in the same way as Experimental Example 1 to obtain the buffer layer of Experimental Example 5. The ratio of the number of S atoms to the number of Zn atoms in the buffer layer was 0.310.

### Experimental Example 6

A buffer layer was formed in the same way as in Experimental Example 1 to obtain the buffer layer of Experimental Example 6. The ratio of the number of S atoms to the number of Zn atoms in the buffer layer was 0.327.

### Experimental Example 7

A buffer layer was formed in the same way as in Experimental Example 1 to obtain the buffer layer of Experimental Example 7. The ratio of the number of S atoms to the number of Zn atoms in the buffer layer was 0.327.

### Experimental Example 8

A buffer layer was formed in the same way as in Experimental Example 1 to obtain the buffer layer of Experimental Example 8. The ratio of the number of S atoms to the number of Zn atoms in the buffer layer was 0.462.

### Experimental Example 9

A buffer layer was formed in the same way as in Experimental Example 1 to obtain the buffer layer of Experimental Example 9. The ratio of the number of S atoms to the number of Zn atoms in the buffer layer was 0.477.

### Experimental Example 10

A buffer layer was formed in the same way as in Experimental Example 1 to obtain the buffer layer of Experimental Example 10. The ratio of the number of S atoms to the number of Zn atoms in the buffer layer was 0.480.

### Experimental Example 11

A buffer layer was formed in the same way as in Experimental Example 1 to obtain the buffer layer of Experimental Example 11. The ratio of the number of S atoms to the number of Zn atoms in the buffer layer was 0.493.

### Experimental Example 12

A first electrode layer including a plurality of layers including Mo was formed on a glass substrate using a sputtering method. Subsequently, a precursor film comprising Cu, In and Ga was formed on the first electrode layer using a sputtering method. A compound-based photoelectric conversion layer comprising Cu(In, Ga)S₂ was then formed by heat-treating (sulfurization) this precursor film under an atmosphere including sulfur. Subsequently, a seed layer was formed by a method in which a Cds film formed using a CBD method and a ZnO film formed using a MOCVD method was arranged to superimpose the compound-based photoelectric conversion layer. Subsequently, a buffer layer was formed on the seed layer using an ALD method in such a manner that the ratio of the number of S atoms to the number of Zn atoms was the same as in Experimental Example 5. Subsequently, an intrinsic zinc oxide film (i-ZnO) was formed on the buffer layer using a MOCVD method. Subsequently, an ITO film as a second electrode layer was formed on the zinc oxide film using an ion plating method to obtain the photoelectric conversion element of Experimental Example 12. The ratio of the number of S atoms to the number of Zn atoms of the photoelectric conversion element of Example 12 is not measured, but it is estimated to be about 0.310 as in Experimental Example 5.

### Comparative Experimental Example 1

A buffer layer of ZnO was formed on a glass substrate using an ALD method to obtain the buffer layer of Comparative Experimental Example 1. Since the buffer layer includes no S, the ratio of the number of S atoms to the number of Zn atoms cannot be determined.

### Comparative Experimental Example 2

A buffer layer of ZnMgO was formed on a glass substrate using an ALD method to obtain the buffer layer of Comparative Experimental Example 2. Since the buffer layer includes no S, the ratio of the number of S atoms to the number of Zn atoms cannot be determined.

### Comparative Experimental Example 3

A buffer layer was formed in the same way as in the above-mentioned Experimental Example 1 to obtain the buffer layer of Comparative Experimental Example 3. The ratio of the number of S atoms to the number of Zn atoms in the buffer layer was 0.186.

### Comparative Experimental Example 4

A buffer layer was formed in the same way as in the above-mentioned Experimental Example 1 to obtain the buffer layer of Comparative Experimental Example 4. The ratio of the number of S atoms to the number of Zn atoms in the buffer layer was 0.186.

### Comparative Experimental Example 5

A buffer layer was formed in the same way as in the above-mentioned Experimental Example 1 to obtain the buffer layer of Comparative Experimental Example 5. The ratio of the number of S atoms to the number of Zn atoms in the buffer layer was 0.189.

### Comparative Experimental Example 6

A buffer layer was formed in the same way as in the above-mentioned Experimental Example 1 to obtain the buffer layer of Comparative Experimental Example 6. The ratio of the number of S atoms to the number of Zn atoms in the buffer layer was 0.189.

### Comparative Experimental Example 7

A buffer layer was formed in the same way as the above-mentioned Experimental Example 1 to obtain the buffer layer of Comparative Experimental Example 7. The ratio of the number of S atoms to the number of Zn atoms in the buffer layer was 0.192.

### Comparative Experimental Example 8

A buffer layer was formed in the same way as in the above-mentioned Experimental Example 1 to obtain the buffer layer of Comparative Experimental Example 8. The ratio of the number of S atoms to the number of Zn atoms in the buffer layer was 0.192.

### Comparative Experimental Example 9

A buffer layer was formed in the same way as in the above-mentioned Experimental Example 1 to obtain the buffer layer of Comparative Experimental Example 9. The ratio of the number of S atoms to the number of Zn atoms in the buffer layer was 0.192.

### Comparative Experimental Example 10

A buffer layer was formed in the same way as in the above-mentioned Experimental Example 1 to obtain the buffer layer of Comparative Experimental Example 10. The ratio of the number of S atoms to the number of Zn atoms in the buffer layer was 0.192.

### Comparative Experimental Example 11

The photoelectric conversion element of Comparative Experimental Example 11 was obtained in the same way as in the above-mentioned Experimental Example 12 except that the buffer layer was formed in the same way as in the above-mentioned Comparative Experimental Example 1.

### Comparative Experimental Example 12

The photoelectric conversion element of Comparative Experimental Example 12 was obtained in the same way as in the above-mentioned Experimental Example 12 except that the buffer layer was formed in the same way as in the above-mentioned Comparative Experimental Example 2.

### Comparative Experimental Example 13

The photoelectric conversion element of Comparative Experimental Example 13 was obtained in the same way as in the above-mentioned Experimental Example 12 except that the buffer layer was formed in the same way as in the above-mentioned Comparative Experimental Example 5. The ratio of the number of S atoms to the number of Zn atoms in the buffer layer of the photoelectric conversion element of Comparative Experimental Example 13 is not measured, but it is estimated to be about 0.189 as in Comparative Experimental Example 5.

The specific resistances of the buffer layers of the above-mentioned Experimental Examples 1 to 11 and Comparative Experimental Examples 1 to 10 were measured. A measurement of a specific resistance was carried out before and after irradiation of artificial sunlight (1000 W/m²) to a buffer layer for a certain time (15 hours). A specific resistance of a buffer layer was measured using a four-terminal method. In addition, a value calculated in such a way that a ratio of the specific resistances before and after irradiation of artificial sunlight was subtracted from 1 (1−(specific resistance after irradiation/specific resistance before irradiation)) was determined as a change rate of specific resistance. The specific resistances and change rates of specific resistances are shown in FIG. 6.

The specific resistances of the buffer layers in Experimental Examples 1 to 11 were larger values than in Comparative Experimental Examples 1 to 10. For example, in comparison between Comparative Experimental Examples 3 to 10 and Examples 1 to 11 in which the buffer layer was formed using the same mixed crystal of ZnO and ZnS, the specific resistances of Experimental Examples 1 to 11 are larger by not less than 2 orders of magnitude than in Comparative Experimental Examples 3 to 10.

In addition, the change rates of specific resistances of Experimental Examples 1 to 11 are not more than 0.10, and in contrast with this, those in Comparative Experimental Examples 1 to 10 are high values of not less than 0.12. Especially, the change rates of specific resistances of Comparative Experimental Examples 1 and 2 in which the buffer layers were formed using a material other than a mixed crystal of ZnO and ZnOS are 0.29 and 0.98, respectively, which shows that the change of the specific resistance by irradiation of artificial sunlight is large.

The buffer layer suppresses leakage current and increases parallel resistance. It is required for the buffer layer to have high specific resistance and low change rate of specific resistance.

The present applicant has considered that the reason why the buffer layers of Experimental Examples 1 to 11 have higher specific resistances and lower change rates of specific resistances than those of Comparative Experimental Examples 1 to 10 is, as one of the cause, that the numbers of defects of the buffer layers of Experimental Examples 1 to 11 are less than those of Comparative Experimental Examples 1 to 10.

The present applicant has considered that the reason why the numbers of defects of the buffer layers of Experimental Examples 1 to 11 are less than those of Comparative Experimental Examples 1 to 10 is that the buffer layer includes a mixed crystal of ZnO and ZnS and the ratio of the number of S atoms to the number of Zn atoms is in the range of 0.290 to 0.493.

As seen above, it is believed that a buffer layer with less defect and good film-quality is obtained by forming the buffer layer in such a manner that the buffer layer includes a mixed crystal of ZnO and ZnS and the ratio of the number of S atoms to the number of Zn atoms is in the range of 0.290 to 0.493.

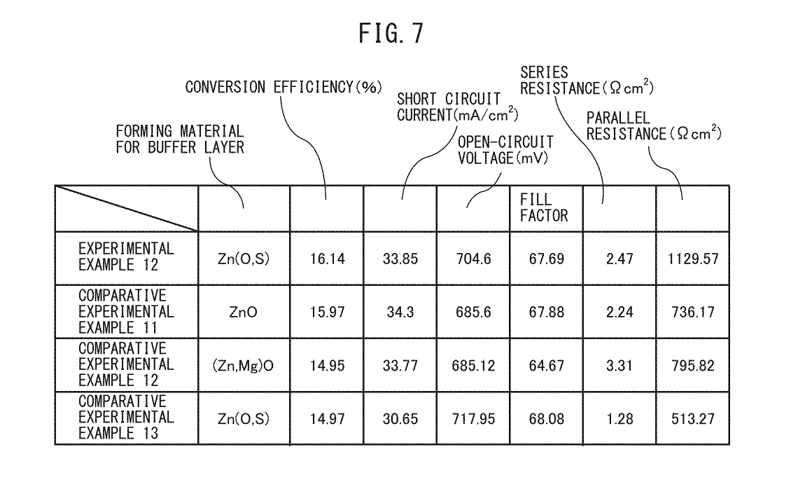

Next, after irradiation of artificial sunlight (1000 W/m²) to the photoelectric conversion elements of Experimental Example 12 and Comparative Experimental Examples 11 to 13 for a certain time (15 hours), a photoelectric conversion efficiency, short circuit current, open-circuit voltage, fill factor, series resistance and parallel resistance were measured. The results of the measurements are shown in FIG. 7.

The photoelectric conversion element of Experimental Example 12 exhibits a photoelectric conversion efficiency of more than 16% and a parallel resistance of more than 1000 Ωcm², which demonstrates more excellent photoelectric conversion efficiency and parallel resistance than those of Comparative Experimental Examples 11 to 13.

It is considered that the buffer layer of the photoelectric conversion element of Experimental Example 12 includes less number of recombination centers caused by defects so that probability of carrier recombination and recombination current are decreased, thereby increasing photoelectric conversion efficiency and increasing parallel resistance. It is believed that parallel resistance is increased more, for example, as leakage current is less.

In the present invention, the photoelectric conversion element of the above-mentioned embodiment can be optionally modified without departing from the scope of the present invention.

For example, the photoelectric conversion element of the above-mentioned Experimental Example includes CIS-based compound semiconductor as a compound-based photoelectric conversion layer, but the photoelectric conversion element may include the other photoelectric conversion layer such as CZTS-based compound semiconductor or CdTe-based compound semiconductor.

This application claims the benefit of Japanese Patent Application No. 2015-205591 filed on Oct. 19, 2015, all the disclosures of Japanese Patent Application No. 2015-205591 are incorporated herein by reference in their entireties.

### REFERENCE SIGN LIST

10 Photoelectric conversion element
11 Substrate
12 First electrode layer
13 Compound-based photoelectric conversion layer
14 Seed layer
15 Buffer layer
16 Second electrode layer

1. A photoelectric conversion element, comprising:
a first electrode layer;
a compound-based photoelectric conversion layer disposed on the first electrode layer;
a buffer layer disposed on the compound-based photoelectric conversion layer, comprising a mixed crystal of ZnO and ZnS, wherein a ratio of the number of S atoms to the number of Zn atoms is in a range of 0.290 to 0.493; and
a second electrode layer disposed on the buffer layer.

2. The photoelectric conversion element according to claim 1, wherein the specific resistance of the buffer layer is not more than 2.59×10 Ωcm.

3. The photoelectric conversion element according to claim 1, comprising a Zn-containing seed layer disposed between the compound-based photoelectric conversion layer and the buffer layer.

4. The photoelectric conversion element according to claim 1, comprising a Zn-containing layer disposed between the second electrode layer and the buffer layer, which Zn-containing layer is an intrinsic semiconductor including ZnO.
